(19) United States
(12) Patent Application Publication
(10) Pub. No.: US 2025/0205797 A1
(43) Pub. Date: Jun. 26, 2025

(54) METHOD OF SOLDERING ELECTRONIC DEVICES AND METHOD OF MANUFACTURING SEMICONDUCTOR PACKAGE

(71) Applicant: SAMSUNG ELECTRONICS CO., LTD., SUWON-SI (KR)

(72) Inventors: KYUNGDEUK MIN, SUWON-SI (KR); SINYEOP LEE, SUWON-SI (KR); TAEGYU KANG, SUWON-SI (KR); MYEONGHYEON YU, SUWON-SI (KR); JAESEON HWANG, SUWON-SI (KR)

(21) Appl. No.: 18/978,040

(22) Filed: Dec. 12, 2024

(30) Foreign Application Priority Data
Dec. 21, 2023 (KR) 10-2023-0188271

(51) Int. Cl. B23K 1/00; B23K 1/005; B23K 101/40; H01L 23/00

(52) U.S. Cl. CPC B23K 1/0016; B23K 1/0056; B23K 2101/40; H01L 24/81; H01L 2224/8122

(57) ABSTRACT

In a method of soldering electronic devices, a lamp heater may be provided, the lamp heater including a light-emitting portion and a shutter portion, wherein the light-emitting portion is configured to irradiate a first irradiation region, a second irradiation region, and a third irradiation region sequentially arranged in a first direction, wherein the shutter portion provides a first shutter configured to block light to the first irradiation region and a second shutter configured to block light to the third irradiation region. A package array may be disposed on a substrate supply actuator, wherein the package array includes a first package and a second package that are sequentially disposed along the first direction. The substrate supply actuator may be moved in the first direction to sequentially pass the package array through the first irradiation region, the second irradiation region and the third irradiation region. Soldering processes may be performed on the first package and the second package by selectively blocking the light to the first irradiation region and the light to the third irradiation region when the first package and the second package moves through the first irradiation region, the second irradiation region, and the third irradiation region.

### CROSS-REFERENCE

This application claims priority under 35 U.S.C. § 119 to Korean Patent Application No. 10-2023-0188271, filed on Dec. 21, 2023, in the Korean Intellectual Property Office (KIPO), the disclosure of which is herein incorporated by reference in its entirety.

### FIELD

The present disclosure generally relates to a method of soldering electronic devices and a method of manufacturing a semiconductor package using the same. More particularly, embodiments may relate to a method of soldering electronic devices using an intense pulsed light (IPL) type of soldering apparatus and/or a method of manufacturing a semiconductor package using the same.

### INTRODUCTION

In a soldering process providing mechanical and electrical connections between electronic devices and a substrate, an intense pulsed light (IPL) method may be used, which may shorten process time and reduce power consumption compared to convection reflow methods. However, since the IPL method directly transfers heat using light, a temperature rise rate of a package subject to the soldering process may vary, potentially to greater than that of some reflow methods. Moreover, a temperature gradient may change rapidly depending on the position of the package, so solder balls at a specific position may be heated and cooled more or less rapidly depending on the position of the package. As a result, some of the solder balls provided on one side portion of the electronic device may be melted first, which may, for example, cause the electronic device to stand vertically due to surface tension of the molten solder balls (e.g., a tombstone defect) or cause the electronic device to be tilted.

### SUMMARY

An embodiment of the present disclosure may provide a method of soldering electronic devices that is capable of reducing a temperature gradient in a package.

An embodiment of the present disclosure may provide a method of manufacturing a semiconductor package by using a presently disclosed soldering method.

According to an embodiment, a method of soldering electronic devices may include providing a lamp heater including a light-emitting portion and a shutter portion, wherein the light-emitting portion is configured to irradiate with light a first irradiation region, a second irradiation region, and a third irradiation region that are sequentially arranged in a first direction, wherein the shutter portion includes a first shutter configured to block the light to the first irradiation region and a second shutter configured to block the light to the third irradiation region; disposing a package array on a substrate supply actuator, wherein the package array includes a first package and a second package that are sequentially disposed along the first direction; moving the substrate supply actuator in the first direction to sequentially pass the package array through the first irradiation region, the second irradiation region and the third irradiation region; and performing soldering processes on the first package and the second package by selectively blocking the light to the first irradiation region and the light to the third irradiation region while the first package and the second package move through the first irradiation region, the second irradiation region and the third irradiation region.

According to an embodiment, a method of soldering electronic devices may include providing a lamp heater including a light-emitting portion and a shutter portion, wherein the light-emitting portion is configured to irradiate with light a first irradiation region, a second irradiation region and a third irradiation region that are sequentially arranged in a first direction, wherein the shutter portion includes a first shutter configured to selectively block the light to the first irradiation region and a second shutter configured to selectively block the light to the third irradiation region; sequentially disposing a first package and a second package in the first direction on a substrate supply actuator to sequentially pass the first package and the second package through the first irradiation region, the second irradiation region and the third irradiation region; moving the substrate supply actuator in the first direction so the second package enters the first irradiation region; irradiating the second package through the first shutter during a first time period while the second package is in the first irradiation region; irradiating the second package during a second time period while moving the second package to the second irradiation region, and blocking the first package from being irradiated using the first shutter during the second time period while moving the first package to the first irradiation region; irradiating the second package during a third time period while the second package is in the second irradiation region; and irradiating the first package through the first shutter during the third time period while the first package is in the first irradiation region; irradiating the first package during a fourth time period while moving the first package to the second irradiation region, and irradiating the second package during the fourth time period while moving the second package to the third irradiation region; irradiating the first package during a fifth time period while the first package is in the second irradiation region, and blocking the second package from being irradiated using the second shutter during the fifth time period while the second package is in the third irradiation region; irradiating the first package during a sixth time period while moving the first package to the third irradiation region, and blocking the second package from being irradiated using the second shutter during the sixth time period while the second package exits the third irradiation region; and blocking the first package from being irradiated while the first package exits the third irradiation region.

According to an embodiment, a method of manufacturing a semiconductor package may include sequentially disposing a plurality of packages on a substrate supply actuator in a first direction; moving the substrate supply actuator in the first direction to sequentially pass the plurality of packages through a first irradiation region, a second irradiation region and a third irradiation region that are sequentially arranged in the first direction; and performing a soldering process on each of the plurality of packages by irradiating the first irradiation region, the second irradiation region and the third irradiation region, and selectively blocking irradiation of the first irradiation region and the third irradiation region while the plurality of packages sequentially move through the first irradiation region, the second irradiation region and the third irradiation region, wherein performing the soldering process includes: irradiating a first package during a first time period while moving the first package into the second irradiation region, and blocking irradiation of a second package while the second package enters the first irradiation region; irradiating the first package and the second package during a second time period while moving the first package to the third irradiation region and moving the second package to the second irradiation region, and blocking irradiation of a third package while the third package enters the first irradiation region; and irradiating the second package and the third package during a third time period while moving the second package to the third irradiation region and moving the third package to the second irradiation region, and blocking irradiation of the first package while the first package exits the third irradiation region.

According to an embodiment, a soldering apparatus may include a lamp heater including a light-emitting portion and a shutter portion, wherein the light-emitting portion is configured to irradiate a first irradiation region, a second irradiation region and a third irradiation region sequentially arranged in a first horizontal direction, wherein the shutter portion includes a first shutter configured to selectively block the light to the first irradiation region and a second shutter to selectively block the light to the third irradiation region; a substrate supply actuator configured to support a package array that includes a first package and a second package sequentially arranged along the first horizontal direction and movable to sequentially pass the first package and the second package through the first irradiation region, the second irradiation region and third irradiation region; and a controller configured to perform a soldering process on each of the first package and the second package by selectively blocking irradiation of the first package and the second package while the first package and the second package sequentially move through the first irradiation region, the second irradiation region and third irradiation region.

According to an embodiment, in a method of soldering electronic devices, a first shutter may be moved from a first external region to a first irradiation region to block light from being irradiated to a package while the package enters an irradiation region. The first shutter may be moved from the first irradiation region to the first external region to allow light to reach the first irradiation region such that the package on the first irradiation region is irradiated by the light. Furthermore, a second shutter may be moved from a third irradiation region to second external region together with the package such that the light is blocked from being irradiated to the package while the package exits from the irradiation regions.

Accordingly, a method of soldering electronic devices may prevent a temperature gradient from occurring when a package included in a package array enters an irradiation region or when the package exits the irradiation region. Additionally, the method of soldering electronic devices may prevent the temperature gradient between packages included in the package array from increasing by equalizing times for which the package is irradiated with light respectively. Thus, it may be possible to prevent tilting of the electronic devices and/or a tombstone defect where the electronic device stands vertically by surface tension of molten solder balls of some of solder balls on one side portion of the electronic device that have melted faster than other solder balls.

### BRIEF DESCRIPTION OF THE DRAWINGS

FIG. 1 is a plan view diagram illustrating a soldering apparatus in accordance with an illustrative embodiment.

FIG. 2 is a cross-sectional view diagram taken along the line A-A′ of FIG. 1.

FIG. 3 is an enlarged view diagram illustrating portion ‘M’ of FIG. 2.

FIG. 4 is a cross-sectional view diagram taken along the line B-B′ of FIG. 3.

FIG. 5 is a cross-sectional view diagram taken along the line C-C′ of FIG. 3.

FIG. 6 is a graphical diagram illustrating temperature versus time for irradiated regions of a package array in accordance with an illustrative embodiment.

FIG. 7 is a cross-sectional diagram of a package array for describing a method of soldering electronic devices in accordance with an illustrative embodiment.

FIG. 8 is a cross-sectional diagram of a package array for describing a method of soldering electronic devices in accordance with an illustrative embodiment.

FIG. 9 is a cross-sectional diagram of a package array for describing a method of soldering electronic devices in accordance with an illustrative embodiment.

FIG. 10 is a cross-sectional diagram of a package array for describing a method of soldering electronic devices in accordance with an illustrative embodiment.

FIG. 11 is a cross-sectional diagram of a package array for describing a method of soldering electronic devices in accordance with an illustrative embodiment.

FIG. 12 is a cross-sectional diagram of a package array for describing a method of soldering electronic devices in accordance with an illustrative embodiment.

FIG. 13 is a cross-sectional diagram of a package array for describing a method of soldering electronic devices in accordance with an illustrative embodiment.

FIG. 14 is a cross-sectional diagram of a package array for describing a method of soldering electronic devices in accordance with an illustrative embodiment.

FIG. 15 is a cross-sectional diagram of a package array for describing a method of soldering electronic devices in accordance with an illustrative embodiment.

FIG. 16 is a cross-sectional diagram of a package array for describing a method of soldering electronic devices in accordance with an illustrative embodiment.

FIG. 17 is a cross-sectional diagram of a package array for describing a method of soldering electronic devices in accordance with an illustrative embodiment.

FIG. 18 is a cross-sectional diagram of a package array for describing a method of soldering electronic devices in accordance with an illustrative embodiment.

FIG. 19 is a cross-sectional diagram of a package array for describing a method of soldering electronic devices in accordance with an illustrative embodiment.

FIG. 20 is a cross-sectional diagram of a package array for describing a method of soldering electronic devices in accordance with an illustrative embodiment.

FIG. 21 is a cross-sectional diagram of a package array for describing a method of soldering electronic devices in accordance with an illustrative embodiment.

FIG. 22 is a cross-sectional diagram of a package array for describing a method of soldering electronic devices in accordance with an illustrative embodiment.

FIG. 23 is a cross-sectional diagram of a package array for describing a method of soldering electronic devices in accordance with an illustrative embodiment.

FIG. 24 is a cross-sectional diagram of a package array for describing a method of soldering electronic devices in accordance with an illustrative embodiment.

FIG. 25 is a cross-sectional diagram of a package array for describing a method of soldering electronic devices in accordance with an illustrative embodiment.

FIG. 26 is a cross-sectional diagram of a package array for describing a method of soldering electronic devices in accordance with an illustrative embodiment.

FIG. 27 is a cross-sectional diagram of a package array for describing a method of soldering electronic devices in accordance with an illustrative embodiment.

### DETAILED DESCRIPTION

Hereinafter, illustrative embodiments will be explained in detail with reference to the accompanying drawings.

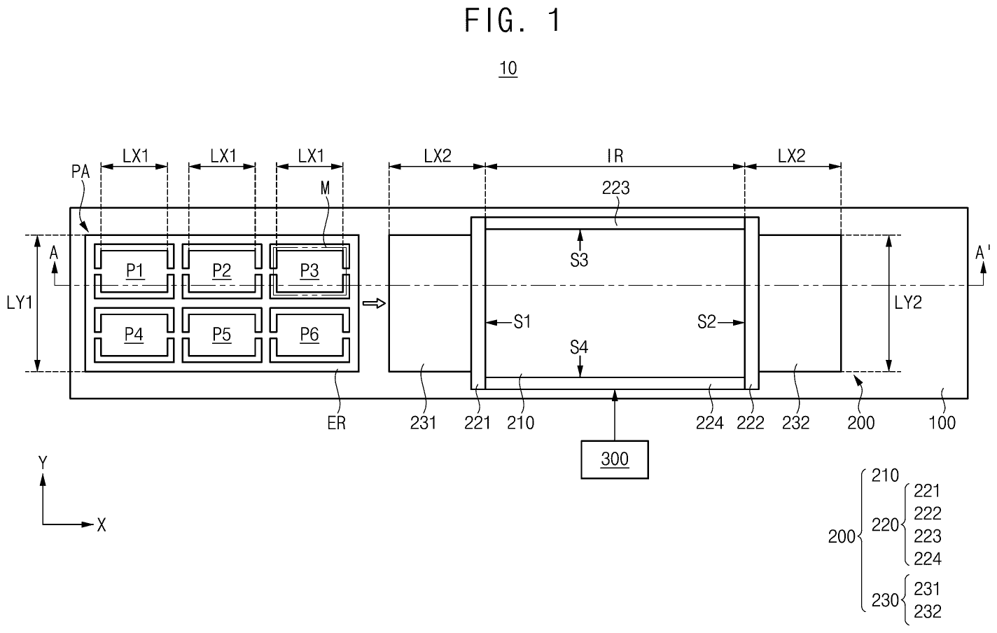

FIG. 1 illustrates a soldering apparatus in accordance with an embodiment.

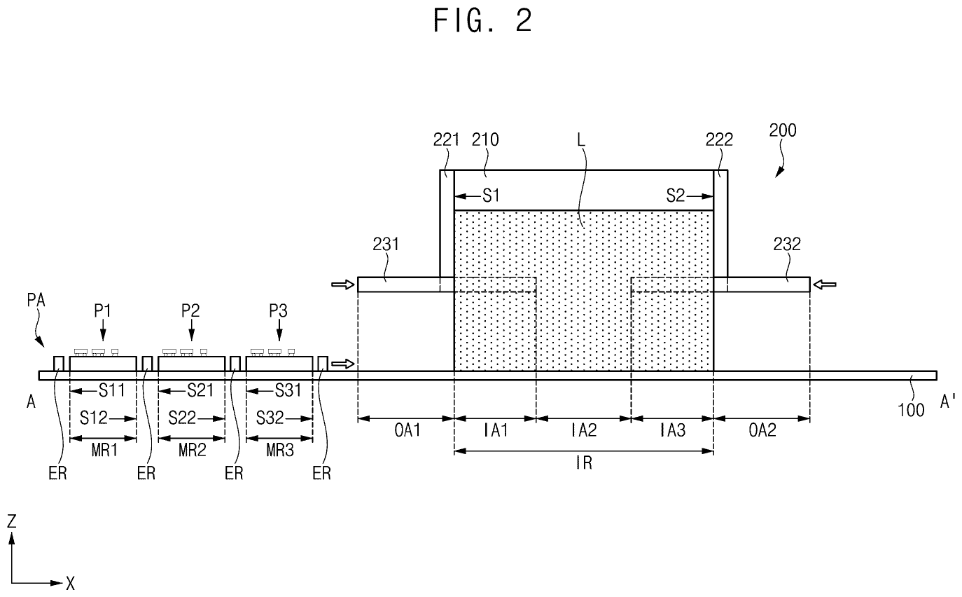

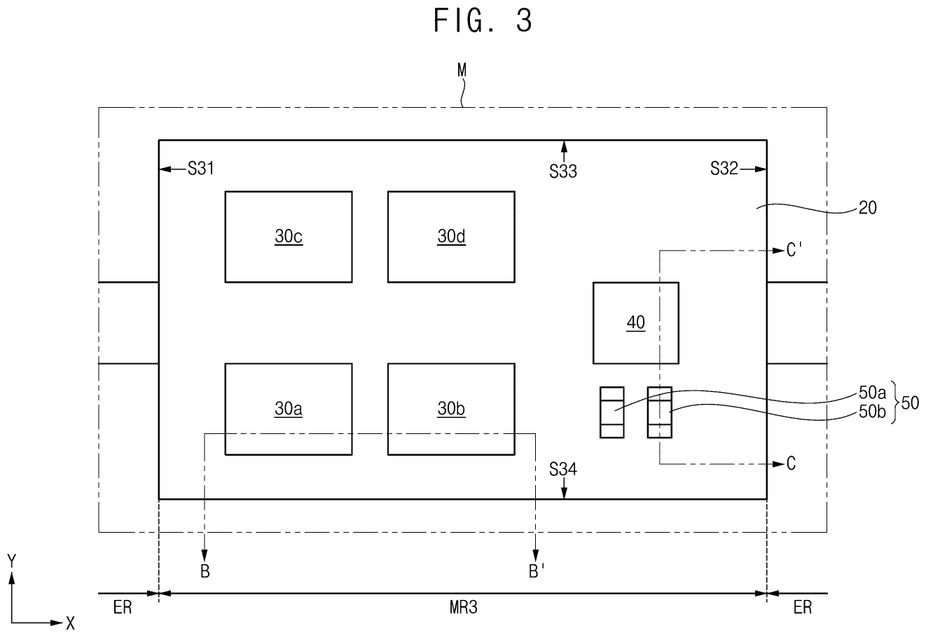

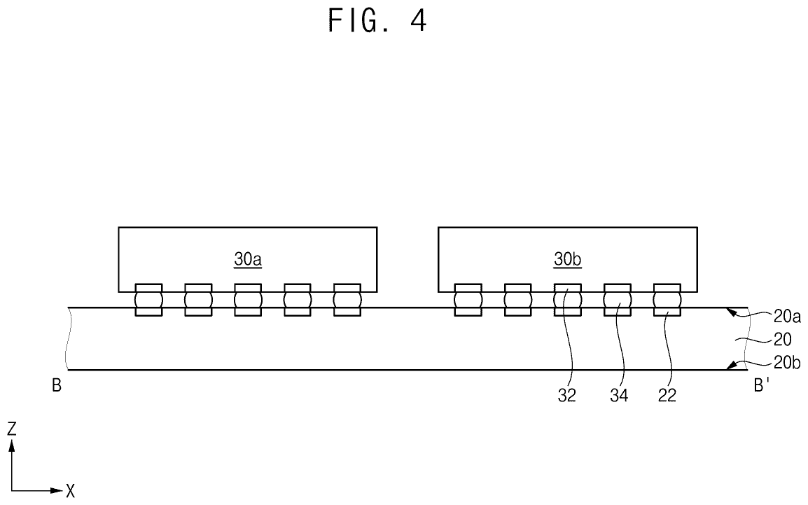

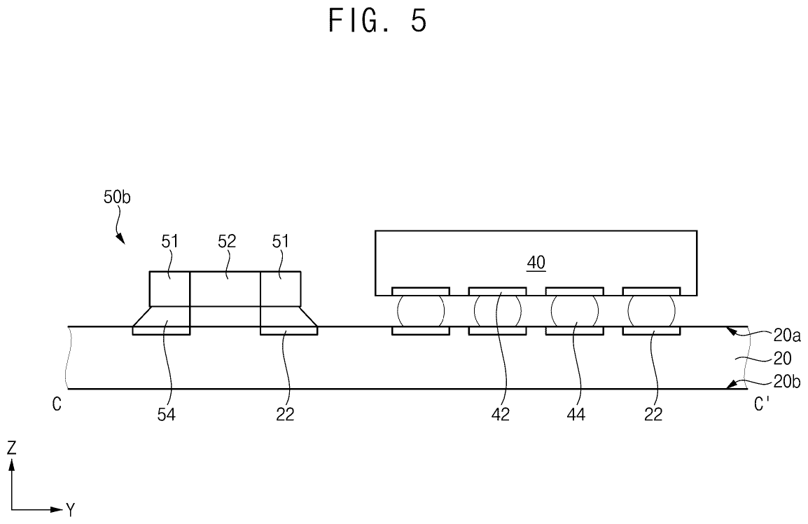

FIG. 2 illustrates a view taken along the line A-A′ of FIG. 1. FIG. 3 illustrates an enlarged view portion ‘M’ of FIG. 2. FIG. 4 illustrates a view taken along the line B-B′ of FIG. 3. FIG. 5 illustrates a view taken along the line C-C′ of FIG. 3.

Referring to FIGS. 1 to 5, a soldering apparatus 10 may include a substrate supply actuator 100 configured to move a package array PA, and a lamp heater 200 configured to irradiate the package array PA with light L relative to the substrate supply actuator 100. Additionally, the soldering apparatus 10 may further include a controller 300 configured to control an operation of a shutter portion 230 that is provided in the lamp heater 200 to perform a soldering process on each of multiple packages in the package array PA.

For example, the soldering apparatus may be an apparatus for mechanically and electrically connecting electronic devices to a module substrate by providing heat to a plurality of connection members, such as solder balls that are interposed between the module substrate included in an individual package of the package array PA, and the electronic devices mounted on the module substrate.

In this specification, a direction in which the package array PA moves may be referred to as a first horizontal direction (X direction), and a horizontal direction perpendicular to the first horizontal direction may be referred to as a second horizontal direction (Y direction), and a direction perpendicular to the first horizontal direction and the second horizontal direction may be referred to as a vertical direction (Z direction).

Hereinafter, the package array PA that is loaded into the soldering apparatus 10 according to an illustrative embodiment will be described, without limitation thereto.

For example, the package array PA may include a plurality of packages (P1, P2, P3, P4, P5 and P6) arranged in a plurality of rows and columns. For example, the package array PA may include a plurality of mounting regions MR1, MR2, and MR3 on which electronic devices are respectively mounted and a dummy region ER excluding the plurality of mounting regions. For example, the dummy region ER of the plurality of packages P1, P2, P3, P4, P5 and P6 may be removed by a following sawing process, such that the packages are individualized into respective single memory module devices. For example, the memory module device may be a solid-state drive (SSD) type of storage device. For example, the SSD device may include a plurality of semiconductor devices such as NAND, DRAM, and a controller.

Although a plurality of packages in the package array are illustrated as being arranged in two rows and three columns, the present inventive concept is not limited thereto, and the number, arrangement, size or the like of the plurality of packages in the package array PA may be varied.

In an embodiment, the package array PA may include a first package P1, a second package P2, and a third package P3 sequentially arranged along the first horizontal or X direction. For example, the first package P1, the second package P2, and the third package P3 may be sequentially and respectively provided on a first mounting area (MR1), a second mounting region (MR2), and a third mounting region (MR3) that are sequentially arranged along the first horizontal or X direction.

Each of the first package P1, the second package P2, and the third package P3 may include a module substrate and a plurality of electronic devices mounted on the module substrate, respectively. Each of the module substrates providing the mounting region may have a plurality of side portions. For example, each of a first module substrate of the first package P1, a second module substrate of the second package P2, and a third module substrate of the third package P3 may include a first substrate side portion S11, S21 and S31 and a second substrate side portion S12, S22 and S32 respectively extending in the second horizontal or Y direction and facing each other.

As illustrated in FIG. 3, for example, the third package P3 may include a module substrate 20, a plurality of first electronic devices 30, a second electronic device 40, and a plurality of third electronic devices 50 respectively mounted on the module substrate 20.

As illustrated in FIG. 4, the module substrate 20 may have an upper surface 20a and a lower surface 20b extending in the first horizontal or X direction and facing each other. Additionally, the module substrate 20 may include a plurality of upper pads 22 exposed on and extending vertically in the Z direction from the upper surface 20a. For example, the plurality of upper pads may be arranged in an array form on the upper surface 20a.

The plurality of first electronic devices 30 may include first to fourth semiconductor devices 30a, 30b, 30c and 30d mounted on the upper surface 20a of the module substrate 20. For example, the plurality of first electronic devices 30 may be mounted on the upper surface 20a of the module substrate 20 via a plurality of first connection members 34 provided between a plurality of first chip pads 32 and the plurality of upper pads 22 of the module substrate 20. For example, the plurality of first electronic devices may include non-volatile memory devices such as flash memory devices, phase-change random-access memory (PRAM) devices, magneto-resistive random-access memory (MRAM) devices, resistive random-access memory (RRAM) devices, and/or volatile memory devices such as static random-access memory (SRAM) devices, dynamic random-access memory (DRAM) devices, or the like.

As illustrated in FIG. 5, the second electronic device 40 may be mounted on the upper surface 20a of the module substrate 20 via a plurality of second connection members 44 provided between a plurality of second chip pads 42 and the plurality of upper pads 22 of the module substrate 20. For example, the second electronic device may include a logic chip including a logic circuit. The logic chip may be a controller that controls memory elements, without limitation. The second electronic device may include a processor chip such as an application processor (AP) and an application-specific integrated circuit (ASIC) as a host such as a central processing unit (CPU), graphics processing unit (GPU), or system on a chip (SOC), without limitation.

The plurality of third electronic devices 50 may include a first electronic element 50a and a second electronic element 50b that are mounted on the upper surface 20a of the module substrate 20. For example, the second electronic element 50b may include a pair of electrodes 51 and a dielectric body 52 provided between the pair of electrodes 51. For example, the plurality of third electronic devices 50 may be mounted on the upper surface 20a of the module substrate 20 via a plurality of third connection members 54 provided between the pair of electrodes 51 and the plurality of upper pads 22 of the module substrate 20. For example, the first electronic element and the second electronic element may each be a multilayer ceramic capacitor to improve the electrical characteristics of the package, without limitation.

The plurality of first connection members 34, the plurality of second connection members 44, and the plurality of third connection members 54 may each include a conductive material for mechanically and electrically connecting the module substrate with the respective electronic devices. For example, the plurality of first connection members 34 and the plurality of second connection members 44 may be solder balls including an alloy of various metals. For example, either the plurality of first connection members 34 and/or the plurality of second connection members 44 may include silver (Au), copper (Cu), tin (Sn), or the like. Additionally, the plurality of third connection members 54 may include solder paste including an alloy of various metals. For example, the plurality of third connection members 54 may include silver (Au), copper (Cu), tin (Sn), or the like that may be materially different than the first and/or second connection members.

Hereinafter, the soldering apparatus 10 according to an illustrative embodiment may be described in greater detail, without limitation thereto.

In an embodiment, the substrate supply actuator 100 may be an apparatus that is configured to move the package array PA along the first horizontal or X direction. For example, the substrate supply actuator may include a conveyor belt or a conveyor chain that is configured to move the package array PA while being in contact with at least a portion of the package array PA. For example, the substrate supply actuator may include a conveyor belt that is configured to move the package array by using a belt that is in contact with a lower surface of the package array PA. For example, the substrate supply actuator may include a conveyor chain that is configured to move the package array PA while being fixed to a side portion of the dummy region ER of the package array PA. Although a movable substrate supply actuator is shown and described, alternate embodiments may employ a stationary substrate platform where the light, shutter and/or irradiation patterns move relative to the substrate platform, without limitation thereto.

The substrate supply actuator 100 may include an irradiation region IR configured to be is irradiated with light L, and first and second external regions OA1 and OA2 disposed in both sides of the irradiation region IR. The first external region OA1, the irradiation region IR, and the second external region OA2 may be sequentially arranged along the first horizontal or X direction. For example, the first external region OA1 may be a region through which the package array PA passes just before entering the irradiation region IR. Additionally, the second external region OA2 may be a region where the package array PA enters after passing through the irradiation region IR.

The irradiation region IR may include a first irradiation region IA1, a second irradiation region IA2, and a third irradiation region IA3 sequentially arranged along the first horizontal or X direction. For example, the first irradiation region IA1 may be a region where individual packages of the package array PA are first irradiated with light just after the individual package enter the irradiation region IR. The third irradiation region IA3 may be a region where the individual packages of the package array PA are last irradiated with light just before the individual packages exit the irradiation region IR. The second irradiation region IA2 may be disposed between the first irradiation region IA1 and the third irradiation region IA3.

In an embodiment, the lamp heater 200 may include a light-emitting portion 210 configured to apply heat to the package array PA by irradiating the package array PA with light L, a blocking portion 220 configured to block the light L from being irradiated to the outside of the irradiation region IR, and a shutter portion 230 disposed on end portions of the blocking portion 220.

For example, the lamp heater may be an intense pulsed light (IPL) type of laser apparatus that directly irradiates an object with light to apply heat to the object. For example, the IPL apparatus may be a heat transfer apparatus that provides radiant heat to an object by using multi-wavelength light generated from a light source such as a xenon lamp. For example, the IPL apparatus may irradiate light by repeating a first state in which light is irradiated (ON state) and a second state in which light is not irradiated (OFF state), for relatively short periods of time. For example, the time for which light is irradiated from the IPL apparatus may be about ‘1.5 ms’. Additionally, the time for which light is not irradiated from the IPL apparatus may be about ‘248 ms’.

In an embodiment, the light-emitting portion 210 may have a lamp that is configured to irradiate light L directly onto the irradiation region IR of the substrate supply actuator 100. The light-emitting portion 210 may provide or include a first side portion S1 and a second side portion S2 extending in the second horizontal or Y direction and facing each other. In addition, the light-emitting portion 210 may provide or include a third side portion S3 and a fourth side portion S4 extends in the first horizontal or X direction and connecting the first side portion S1 and the second side portion S2.

In an embodiment, the blocking portion 220 may prevent light of the light-emitting portion 210 from being irradiated to the outside of the irradiation region IR. The blocking portion 220 may include a plurality of side walls 221, 222, 223 and 224 that respectively extend along the vertical or Z direction from the plurality of side portions S1, S2, S3 and S4 of the light-emitting portion 210 toward the substrate supply actuator 100.

For example, the blocking portion 220 may provide a first side wall 221 and provided on the first side portion S1 of the light-emitting portion 210 to extend in the second horizontal or Y direction and a second side wall 222 provided on the second side portion S2 of the light-emitting portion 210 to face the first side wall 221. In addition, the blocking portion 220 may provide a third side wall 223 and a fourth side wall 224 extending in the first horizontal or X direction to connect between the first side wall 221 and the second side wall 222. For example, the first side wall 221 may be provided at a boundary portion between the irradiation region IR of the substrate supply actuator 100 and the first external region OA1, and the second side wall 222 may be provided at a boundary portion between the irradiation region IR and the second external region OA2.

In an embodiment, the shutter portion 230 may include a first shutter 231 that is provided on an end portion of the first side wall 221 to extend in the first horizontal or X direction toward the outside of the irradiation region IR and a second shutter 232 that is provided on an end of the second side wall 222 to extend in the first horizontal or X direction toward the outside of the irradiation region IR. For example, the shutter portion may be a structure that is configured to block the irradiation of a package in the package array (PA). For example, as described above, the package array PA may include a plurality of packages arranged in a plurality of columns and rows. In such a case, the first shutter and the second shutter may block the irradiation of the packages arranged in a specific column of the package array PA, without limitation thereto.

The first shutter 231 and the second shutter 232 may be movable in the first horizontal or X direction.

For example, the first shutter 231 may be movable along the first horizontal or X direction over the first external region OA1 and the first irradiation region IA1 by a driving portion provided on the end portion of the first side wall 221. For example, the first shutter 231 may be provided over the package entering the irradiation region IR to block irradiation of the package. Accordingly, the first shutter may prevent a sudden increase in temperature gradient from occurring while the package enters the irradiation region.

For example, the second shutter 232 may be movable along the first horizontal or X direction over the second external region OA2 and the third irradiation region IA3 by a driving portion provided on the end portion of the second side wall 222. For example, the second shutter 232 may be provided over the package exiting the irradiation region IR to block irradiation of the package. Accordingly, the second shutter may prevent a sudden increase in temperature gradient from occurring while the package exits the irradiation region.

Sizes of the first shutter 231 and the second shutter 232 may be determined in consideration of a size of the package array PA and sizes of the packages included in the package array PA.

For example, widths in the first horizontal direction X direction of the plurality of packages P1, P2, P3, P4, P5 and P6 included in the package array PA may have a first width LX1. Widths in the first horizontal or X direction of the first shutter 231 and the second shutter 232 may have a second width LX2. The second width LX2 may be equal to or greater than the first width LX1.

For example, a length in the second horizontal or Y direction of the package array PA may have a first length LY1. Lengths in the second horizontal or Y direction of the first shutter 231 and the second shutter 232 may have a second length LY2. The second length LY2 may be equal to or greater than the first length LY1, without limitation thereto.

In an embodiment, the controller 300 may control operations of the lamp heater 200 and the substrate supply actuator 100. For example, when each of the first to third packages P1, P2 and P3 sequentially pass through the first irradiation region IA1, the second irradiation region IA2, and the third irradiation region IA3, the controller 300 may control to selectively block irradiation of the first irradiation region IA1 and the third irradiation region IA3 to perform a soldering process on each of the first, second and the third packages P1, P2 and P3 by.

As described above, the soldering apparatus 10 may include the substrate supply actuator 100 configured to move the package array PA, the lamp heater 200 configured to irradiate light L onto the substrate supply actuator 100 and including the shutter portion 230 that is configured to partially block the irradiated light L, and the controller 300 configured to control the operation of the shutter portion 230 to perform a soldering process on each of the packages included in the package array PA.

The shutter portion 230 may include the first shutter 231 that is movable along the first horizontal or X direction to selectively block the irradiation of the first irradiation region IA1 and the second shutter 232 that is movable along the first horizontal or X direction to selectively block the irradiation of the third irradiation region IA3. Additionally, the first shutter 231 and the second shutter 232 may block light that is irradiated to a specific package of the package array PA, among light that would otherwise irradiate the package array PA.

Accordingly, the soldering apparatus may reduce a temperature gradient or difference among the plurality of packages included in the package array. Additionally, the soldering apparatus may reduce a temperature gradient depending on a location of a single package.

Hereinafter, a method of soldering electronic devices in accordance with an embodiment will be described.

Referring again to FIGS. 1 to 5, the soldering apparatus 10 according to an embodiment may be provided for a soldering process, and a package array PA that is an object of the soldering process may be provided. The soldering apparatus 10 and the package array PA provided in the soldering process according to an embodiment may be substantially the same as the soldering apparatus 10 and the package array (PA) described in FIGS. 1 to 5, so repeated descriptions for same elements may be omitted.

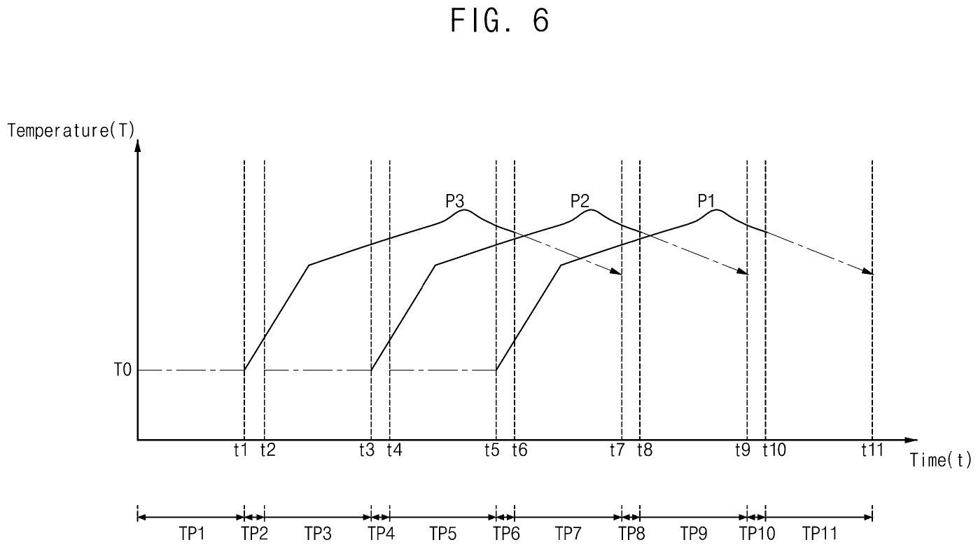

FIG. 6 is a graph illustrating temperature profiles of soldering processes of respective packages in a package array in accordance with an embodiment.

Referring to FIG. 6, in case where a soldering process is performed for the package array PA using a method of soldering electronic devices in accordance with an embodiment, temperature profiles for first to third packages P1, P2 and P3 included in the package array PA may be respectively obtained, wherein the temperature gradient among the first to third packages P1, P2 and P3 may be minimized. Since substantially the same soldering processes are performed on the first to third packages P1, P2 and P3, respectively, the temperature profiles of the first to third packages P1, P2 and P3 may have the substantially the same graphical form.

For example, the soldering process may be divided into first to eleventh time periods TP1, TP2, TP3, TP4, TP5, TP6, TP7, TP8, TP9, TP10 and TP11, depending on the controlled movements of the first shutter 231 and the second shutter 232. The first time period TP1, the third time period TP3, and the fifth time period TP5 may be periods where the first to third packages P1, P2 and P3 enter the first irradiation region IA1, respectively. In these periods, the first shutter 231 may be moved to enter the first irradiation region IA1 together with each of the first to third packages P1, P2 and P3 to be disposed over each of the first to third packages P1, P2 and P3. The seventh time period TP7, the ninth time period TP9, and the eleventh time period TP11 may be periods where the first to third packages P1, P2 and P3 exits the third irradiation region IA3 respectively. In these periods, the second shutter 232 may be moved to exit the third irradiation region IA3 together with each of the first to third packages P1, P2 and P3 to be disposed over each of the first to third packages P1, P2 and P3. The second time period TP2, the fourth time period TP4, and the sixth time period TP6 may be periods where the first shutter 231 moves from the first irradiation region IA1 to the first external region OA1 to begin to irradiate light L onto the first irradiation region IA1. The sixth time period TP6, the eighth time period TP8, and the tenth time period TP10 may be periods where the second shutter 232 moves from the second external region OA2 to the third irradiation region IA3 to begin to block the light L that would otherwise irradiate the third irradiation region IA3.

For example, the first time period TP1, the third time period TP3, the fifth time period TP5, the seventh time period TP7, the ninth time period TP9, and the eleventh time period TP11 may have a same time interval. Further, the second time period TP2, the fourth time period TP4, the sixth time period TP6, the eighth time period TP8, and the tenth time period TP10 may have a same time interval. Thus, the same soldering processes may be performed on the first to third packages P1, P2 and P3 such that each of packages is irradiated with light L for the same amount of time.

For example, each of the first to third packages P1, P2 and P3 may have the highest temperature when passing through the third irradiation region IA3 because each of the first to third packages P1, P2 and P3 is irradiated with light L for the longest time period when passing through the third irradiation region IA3. For example, the third package P3 may reach a peak temperature within the fifth time period TP5, the second package P2 may reach a peak temperature within the seventh time period TP7, and the first package P1 may reach a peak temperature within the ninth time period TP9. For example, the plurality of conductive connecting members of each of the first to third packages P1, P2 and P3 may be soldered near the time of reaching the peak temperatures. respectively.

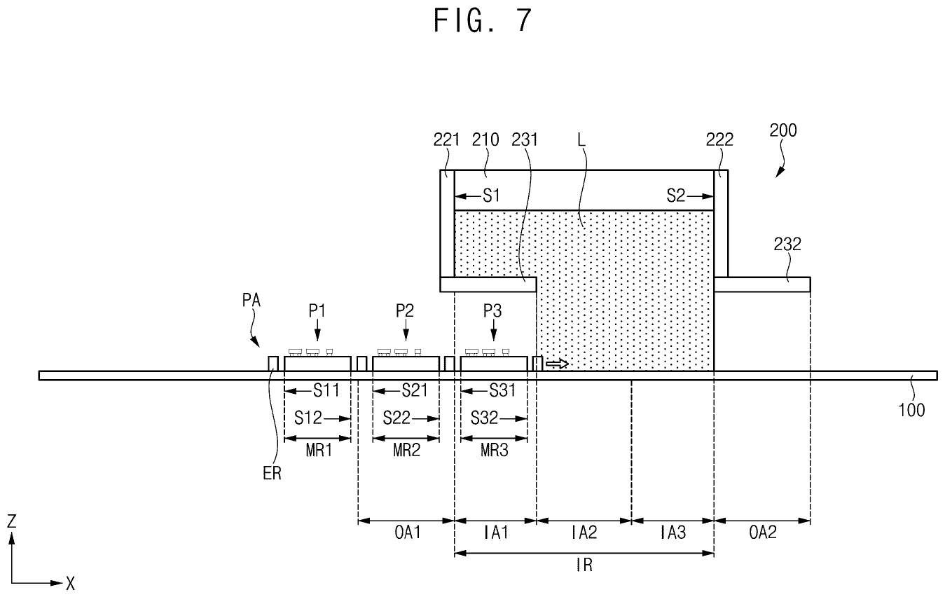

FIG. 7 is a cross-sectional view illustrating the package array entered into the irradiation region in the first time period TP1 of FIG. 6.

Referring to FIG. 7, after the first shutter 231 is disposed on the first irradiation region IA1, the third package P3 of the package array PA may enter the irradiation region IR. For example, the time from when the third package P3 enters the first irradiation region IA1 to when the third package completely enters the first irradiation region IA1 may be the first time period TP1. Since the first shutter 231 blocks the light L irradiated onto the third package P3 during the first time period TP1, the temperature of the third package P3 may not increase. For example, the temperature of the third package P3 may be room temperature T0.

For example, the first shutter 231 may be disposed on the first irradiation region IA1 before the third package P3 of the package array PA enters the irradiation region IR. Accordingly, the third package P3 may block irradiation of the third package P3 while entering the irradiation region (IR), so it may be possible to prevent portions of connecting members included in the third package P3 from heating up first.

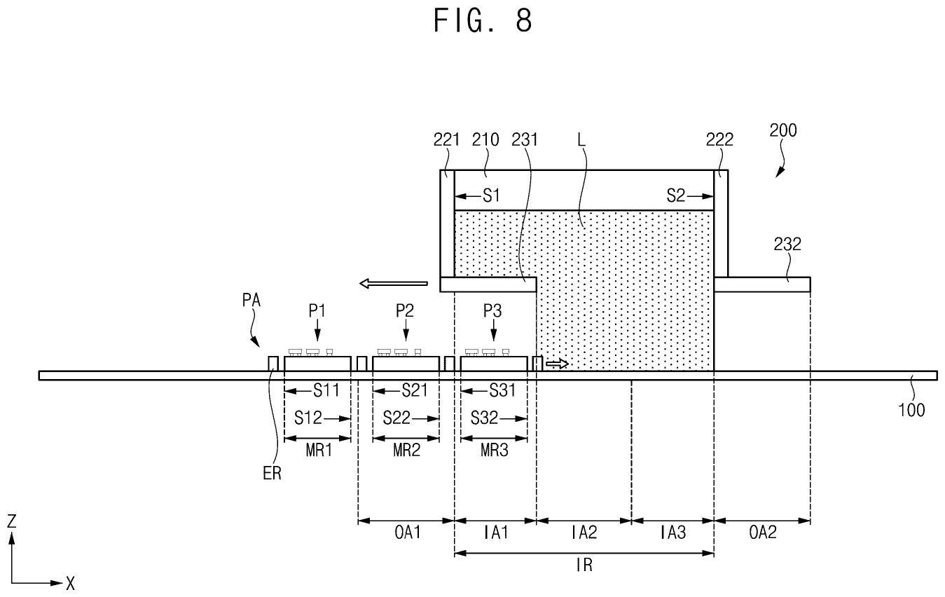

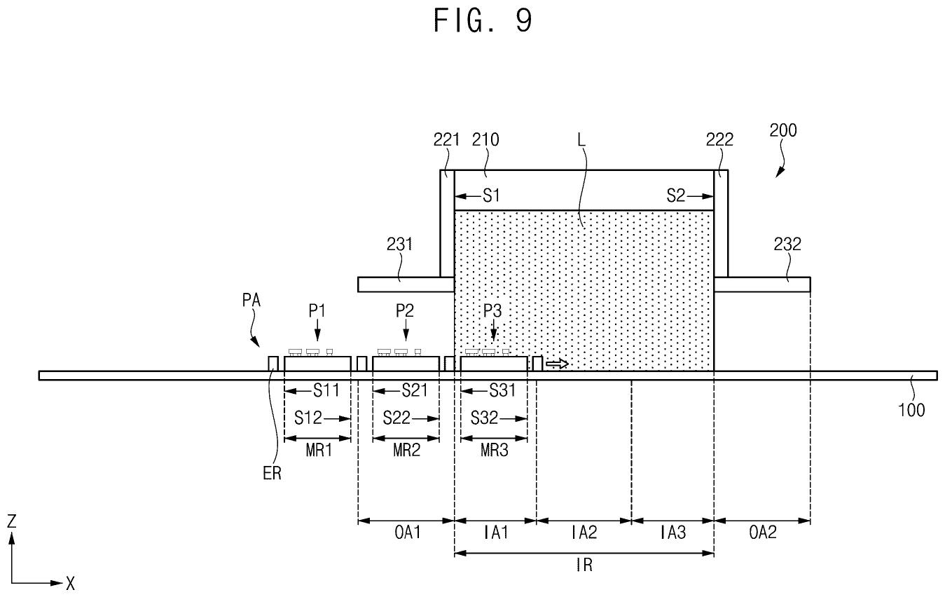

FIGS. 8 and 9 are cross-sectional views illustrating the package array irradiated by light in the second time period TP2 of FIG. 6.

Referring to FIGS. 8 and 9, by moving the first shutter 231 from the first irradiation region IA1 to the first external region OA1, light L may irradiate the third package P3 disposed on the first irradiation region IA1. For example, the time period when the first shutter 231 moves from the first irradiation region IA1 to the first external region OA1 after the third package P3 enters the first irradiation region IA1 may be the second time period TP2. During the second time period TP2, light L may begin to irradiate the third package P3 disposed in the first irradiation region, causing the temperature of the third package P3 to rise.

For example, the first shutter 231 may move relatively quickly from the first irradiation region IA1 to the first external region OA1. For example, the first shutter 231 may move from the first irradiation region IA1 to the first external region OA1 while the light is not irradiated from the lamp heater 200 (OFF state). For example, the time period for which the light is not irradiated by the lamp heater 200 may be about ‘248 ms’. Thus, while moving the first shutter 231 from the first irradiation region IA1 to the first external region OA1, an increase in the temperature gradient in the third package P3 may be prevented.

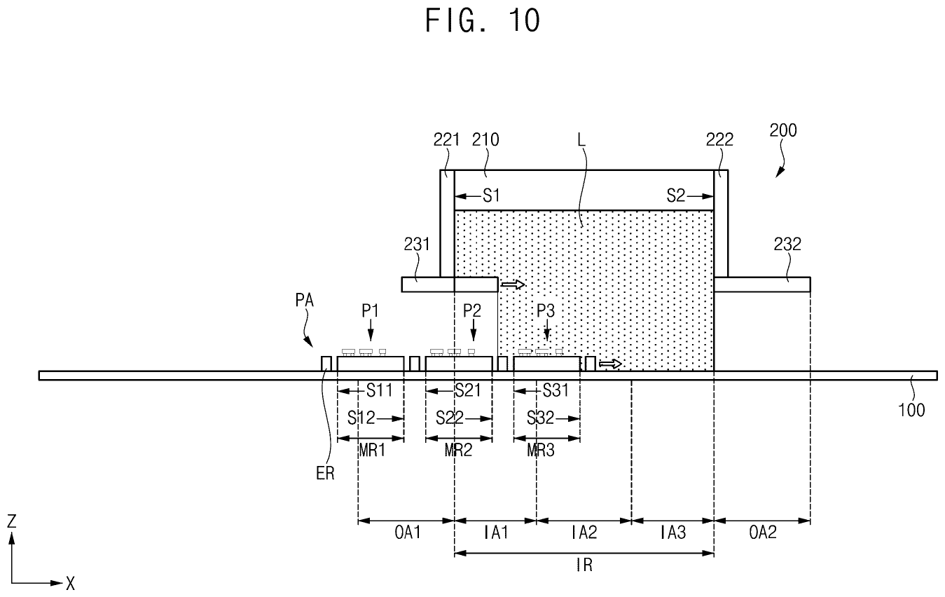

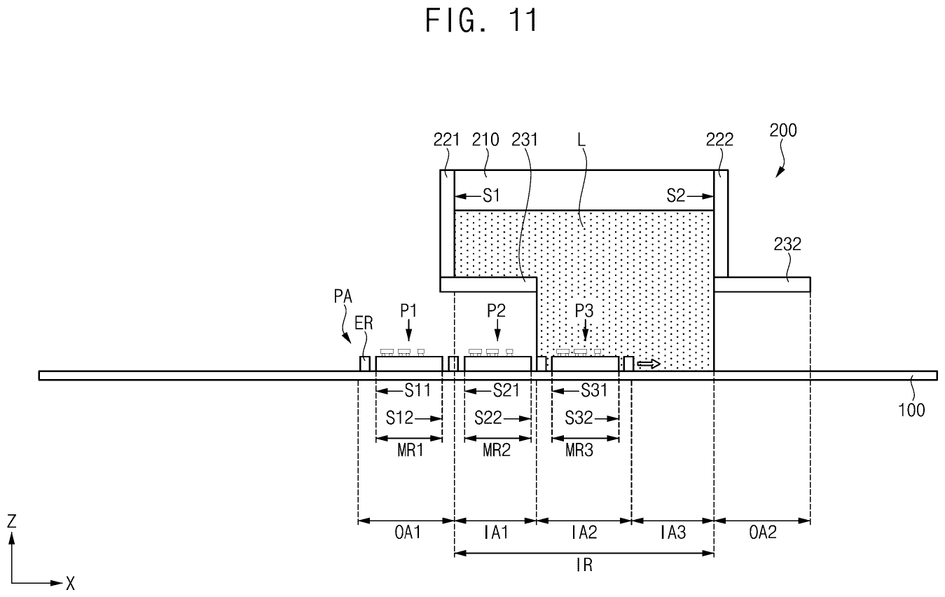

FIGS. 10 and 11 are cross-sectional views illustrating the package array irradiated by light in the third time period TP3 of FIG. 6.

Referring to FIGS. 10 and 11, the second package P2 and the first shutter 231 disposed over the second package P2 may be moved together from the first external region OA1 to the first internal region IA1 so that the second package P2 enters the irradiation region IR while blocking the light L that would otherwise irradiate the second package P2. In addition, while the second package P2 enters the first irradiation region IA1, the third package P3 may move from the first irradiation region IA1 to the second irradiation region IA2, and light L may be continuously irradiated onto the third package P3.

For example, the time period for the third package P3 to move from the first irradiation region IA1 to the second irradiation region IA2 may be a third time period TP3. During the third time period TP3, light may irradiate the third package P3 to increase the temperature of the third package P3. On the contrary, the first shutter 231 may block the light L irradiated onto the second package P2 during the third time period TP3, so the temperature of the second package P2 may not increase. For example, the temperature of the second package P2 may be room temperature T0. For example, the second package P2 and the first shutter 231 may move in the first horizontal or X direction at the same speed. The second package P2 and the first shutter 231 may move relatively slowly. For example, a moving speed of the second package P2 and the first shutter 231 may be about ‘10 mm/s’.

For example, a length in the first horizontal or X direction of the first shutter 231 may be greater than or equal to a length in the first horizontal or first direction of the second package P2. Additionally, the first shutter 231 may be moved depending on a position of the second side portion S22 of the second package P2. Accordingly, since the light is blocked that would otherwise irradiate the second package P2 while entering the irradiation region IR, it may be possible to prevent portions of connecting members included in the second package P2 from heating up first.

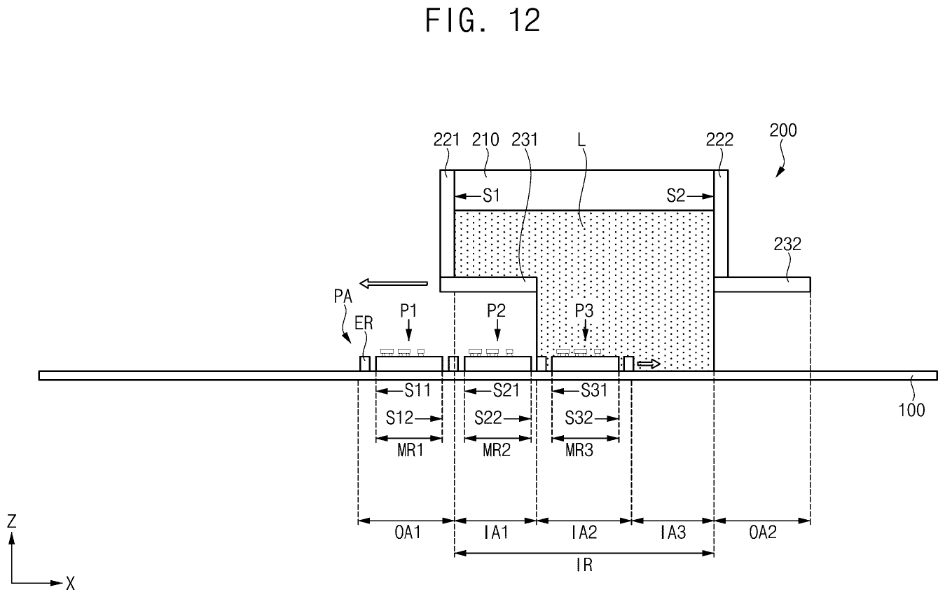

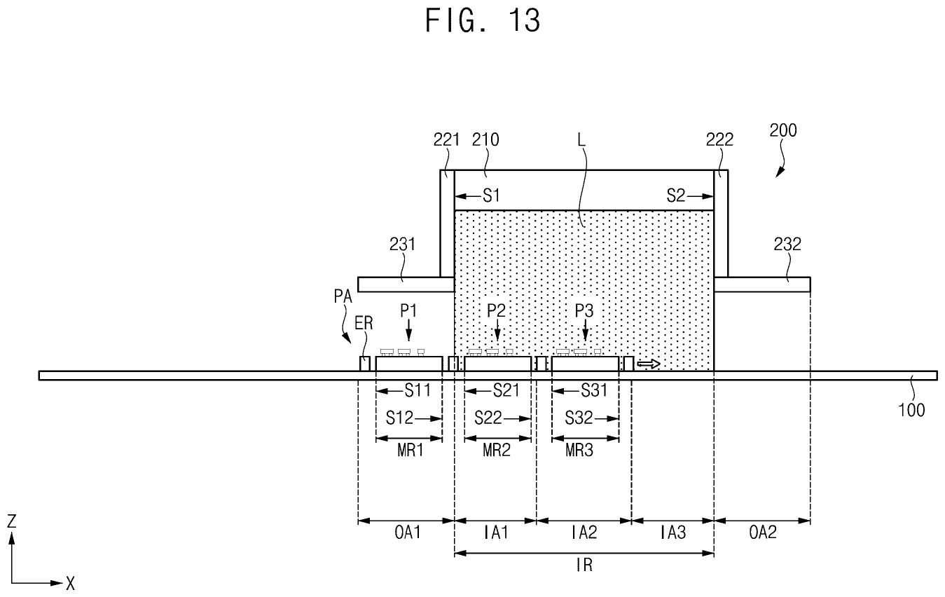

FIGS. 12 and 13 are cross-sectional views illustrating the package array irradiated by light in the fourth time period TP4 of FIG. 6.

Referring to FIGS. 12 and 13, the first shutter 231 may be moved from the first irradiation region IA1 to the first external region OA1, so that the first shutter 231 may allow light L to irradiate the second package P2 provided on the first irradiation region IA1. For example, the time period when the first shutter 231 move from the first irradiation region IA1 to the first external region OA1 after the second package P2 enters the first irradiation region IA1 may be the fourth time period TP4. During the fourth time period TP4, light L may begin to irradiate the second package P2 disposed on the first irradiation region IA1, so the temperature of the second package P2 may increase. Additionally, during the fourth time period TP4, the light L may continue to irradiate the third package P3 disposed on the second irradiation region IA2, so the temperature of the third package P3 may increase.

For example, the first shutter 231 may move relatively quickly from the first irradiation region IA1 to the first external region OA1. For example, while the light irradiated from the lamp heater 200 is turned off, the first shutter 231 may move from the first irradiation region IA1 to the first external region OA1. For example, the time period for which the light irradiated from the lamp heater is turned off may be about ‘248 ms’. Accordingly, while moving the first shutter 231 from the first irradiation region IA1 to the first external region OA1, an increase in the temperature gradient in the second package P2 may be prevented.

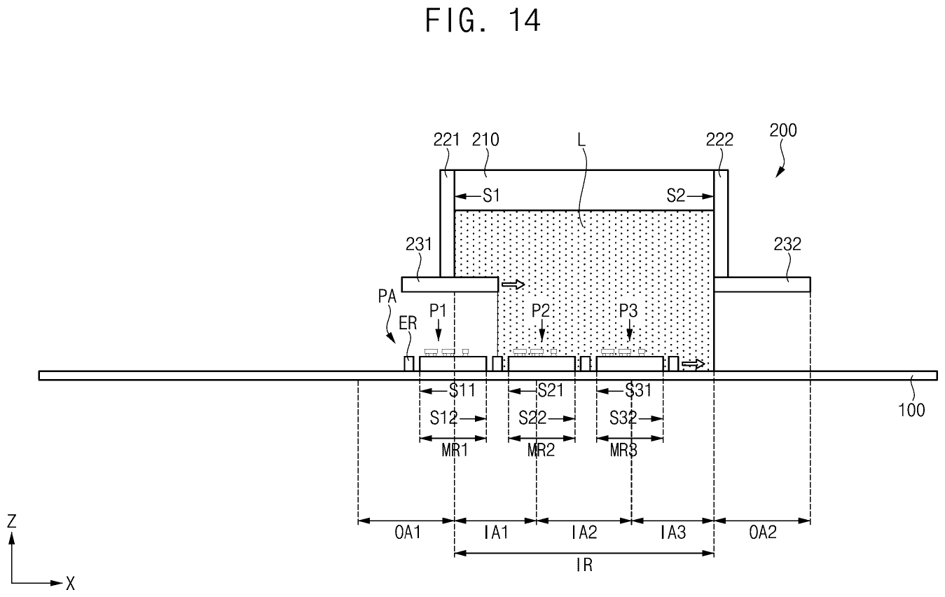

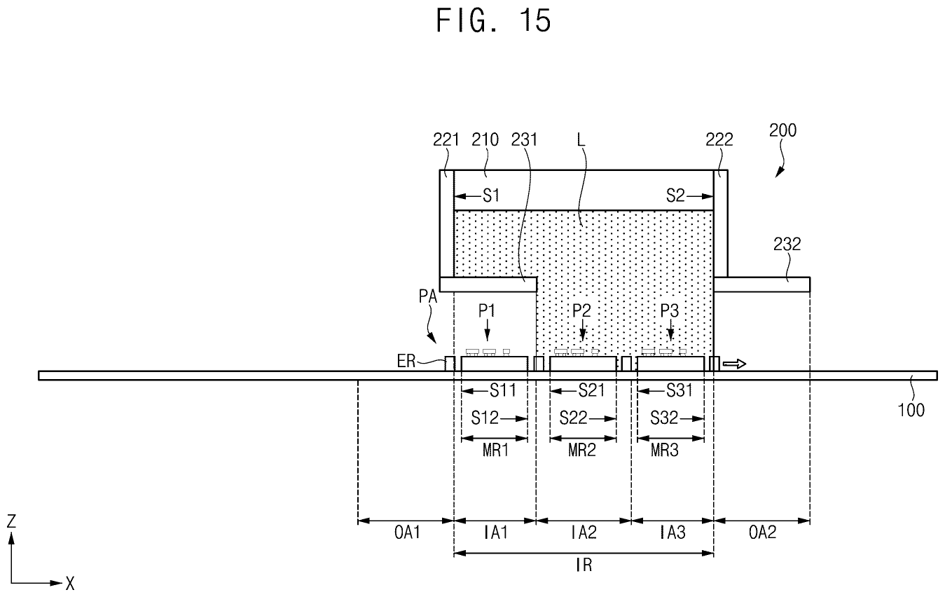

FIGS. 14 and 15 are cross-sectional views illustrating the package array irradiated by light in the fifth time period TP5 of FIG. 6.

Referring to FIGS. 14 and 15, the first package P1 and the first shutter 231 disposed over the first package P1 may be moved together from the first external region OA1 to the first irradiation region IA1 so the first package P1 enters the irradiation region IR while blocking the light L that would otherwise irradiate the first package P1. Om addition, while the first package P1 enters the first irradiation region IA1, the second package P2 may be moved from the first irradiation region IA1 to the second irradiation region IA2, and light L may be continuously irradiated onto the second package P2. Further, while the first package P1 enters the first irradiation region IA1, the third package P3 may be moved from the second irradiation region IA2 to the third irradiation region IA3, and light L may be continuously irradiated onto the third package P3.

For example, the time period for the second package P2 to move from the first irradiation region IA1 to the second irradiation region IA2 and the time period for the third package P3 to move from the second irradiation region IA2 to the third irradiation region IA3 may be the fifth time period TP5. During the fifth time period TP5, the second package P2 and the third package P3 may be irradiated with light, so the temperature of the second package P2 and the third package P3 may increase. In contrast, the light L that would otherwise irradiate the first package P1 during the fifth time period TP5 may be blocked by the first shutter 231, so the temperature of the first package P1 may not increase. For example, the temperature of the first package P1 may be room temperature T0.

For example, the first package P1 and the first shutter 231 may move in the first horizontal or X direction at the same speed. The first package P1 and the first shutter 231 may move relatively slowly. For example, a moving speed of the first package P1 and the first shutter 231 may be about “10 mm/s”.

For example, a length in the first horizontal or X direction of the first shutter 231 may be greater than or equal to a length in the first horizontal or X direction of the first package P1. Further, the first shutter 231 may be move depending on a position of a second side portion S12 of the first package P1. Thus, the irradiation of the first package P1 may be blocked while the first package P1 enters the irradiation region IR, so that it may be possible to prevent portions of some of connecting members included in the first package P1 from first heating up.

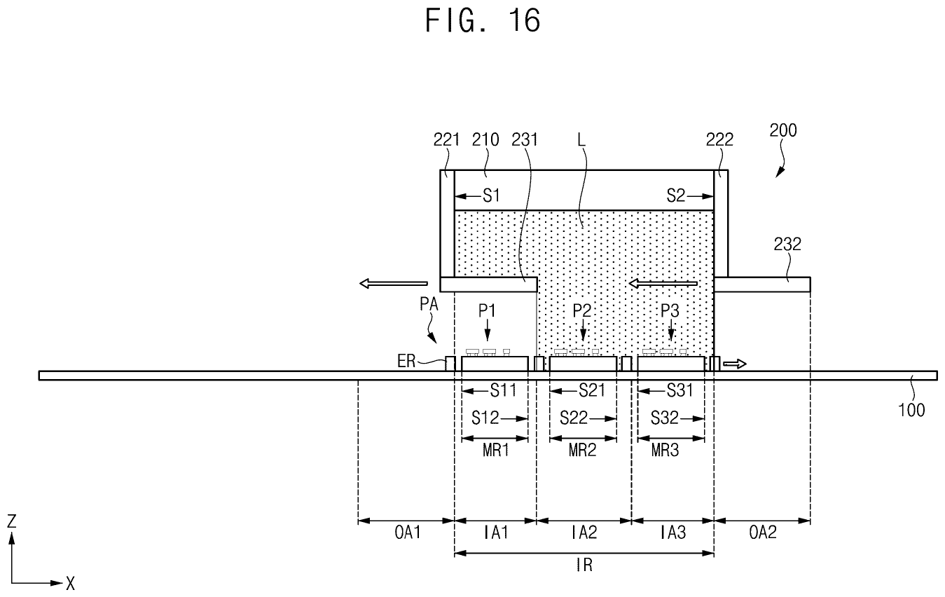

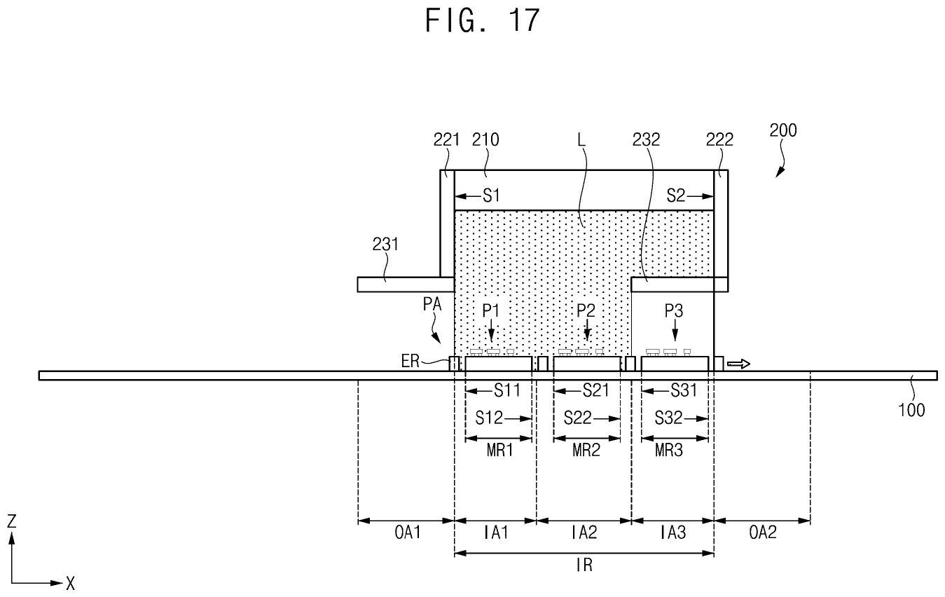

FIGS. 16 and 17 are cross-sectional views illustrating a package array irradiated by light in the sixth time period TP6 of FIG. 6.

Referring to FIGS. 16 and 17, the first shutter 231 may be moved from the first irradiation region IA1 to the first external region OA1, so that the first shutter 231 may allow light L to irradiate the first package P1 provided on the first irradiation region IA1. In addition, the second shutter 232 may be moved from the second external region OA2 to the third irradiation region IA3, so that the second shutter 232 may block the irradiation of the third package P3 provided on the third inner region IA3. Additionally, light L may continue to irradiate the second package P2 provided on the second irradiation region IA2.

For example, the time period when the first shutter 231 moves from the first irradiation region IA1 to the first external region OA1 after the first package P1 enters the first irradiation region IA1 may be the sixth time period TP6. In addition, the time period for the second shutter 232 to move from the second external region OA2 to the third irradiation region OA3 after the third package P3 enters the third irradiation region IA3 may be the sixth time period TP6. During the sixth time period TP6, light L may begin to irradiate the first package P1 disposed on the first irradiation region IA1, so the temperature of the first package P1 may increase. In contrast, during the sixth time period TP6, the light L irradiated onto the third package P3 disposed on the third irradiation region IA3 may begin to be blocked, so the temperature of the third package P3 may decrease.

For example, the first shutter 231 may move relatively quickly from the first irradiation region IA1 to the first external region OA1. For example, while the light irradiated from the lamp heater 200 is turned off, the first shutter 231 may move from the first irradiation region IA1 to the first external region OA1. For example, the time period during which the light irradiated from the lamp heater is repeatedly turned off may be about ‘248 ms’. Accordingly, while moving the first shutter 231 from the first irradiation region IA1 to the first external region OA1, an increase in the temperature gradient in the first package P1 may be prevented.

For example, the second shutter 232 may move relatively quickly from the second external region OA2 to the third irradiation region IA3. For example, while the light irradiated from the lamp heater 200 is turned off, the second shutter 232 may move from the second external region OA2 to the third irradiation region IA3. For example, the time period during which the light irradiated from the lamp heater is repeatedly turned off may be about ‘248 ms’. Accordingly, while moving the second shutter 232 from the second external region OA2 to the third irradiation region IA3, an increase in the temperature gradient in the third package P3 may be prevented.

For example, moving time period of the first shutter 231 and moving time period of the second shutter 232 may be the same as the sixth section. Accordingly, at the same time period as the first package P1 begin to be irradiated, the light irradiated to the third package P3 may be blocked, thereby preventing the temperature gradient difference between the packages in the package array PA from increasing.

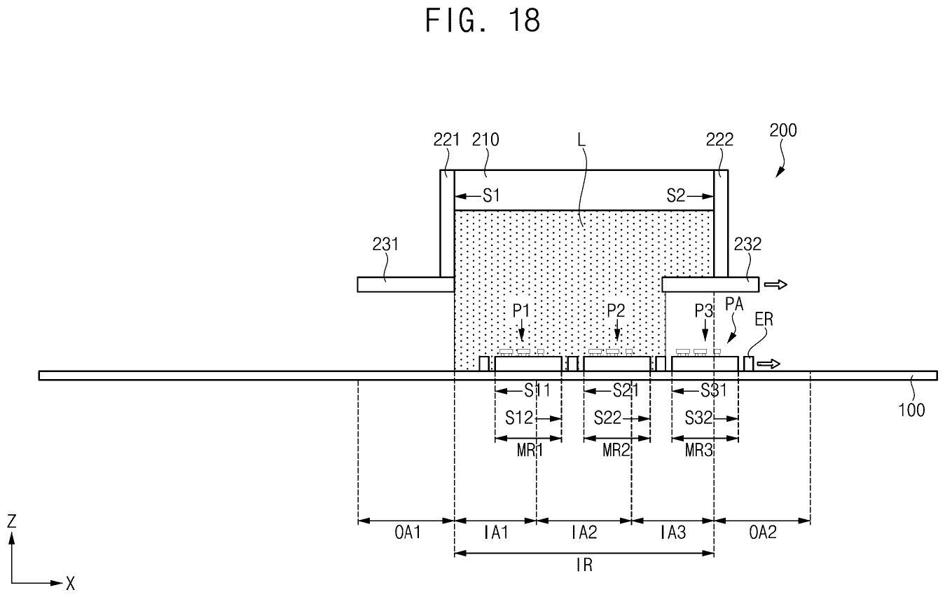

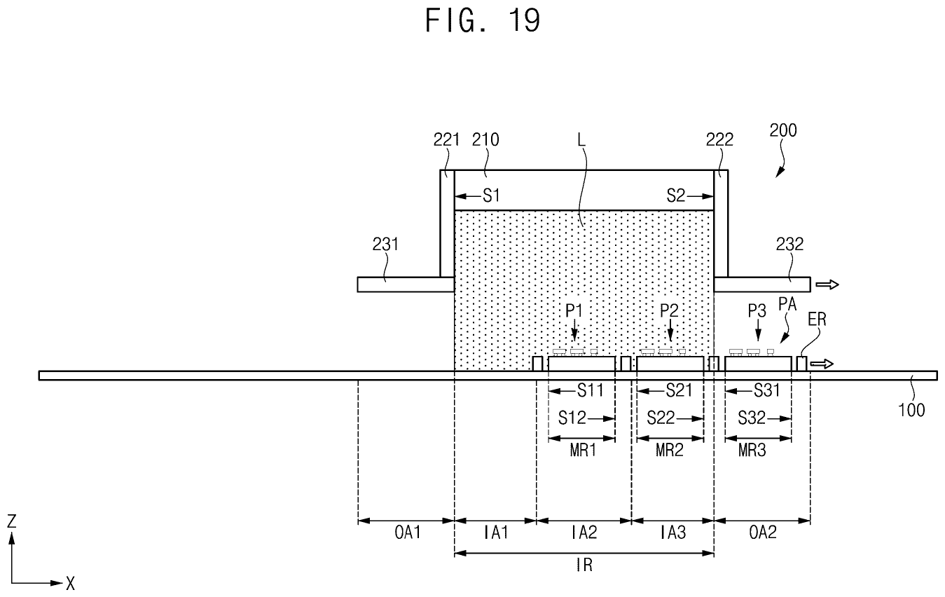

FIGS. 18 and 19 are cross-sectional views illustrating the package array irradiated by light in the seventh time period TP7 of FIG. 6.

Referring to FIGS. 18 and 19, the third package P3 and the second shutter 232 disposed over the third package P3 may be moved together from the third irradiation region OA3 to the second external region OA2. Thus, the third package P3 may exit the irradiation region IR while blocking the light L that would otherwise irradiate the third package P3. In addition, while the third package P3 exits the third irradiation region IA3, the first package P1 may be moved from the first irradiation region IA1 to the second irradiation region IA2, and light L may irradiate the first package P1. In addition, while the third package P3 exits the third irradiation region IA3, the second package P2 may be moved from the second irradiation region IA2 to the third irradiation region IA3, and light L may be radiated onto the second package P2.

For example, the time period for the first package P1 to move from the first irradiation region IA1 to the second irradiation region IA2 and the time period for the second package P2 to move from the second irradiation region IA2 to the third irradiation region IA3 may be the seventh time period TP7. During the seventh time period TP7, light may irradiate the first package P1 and the second package P2, so the temperatures of the first package P1 and the second package P2 may increase. In contrast, the second shutter 232 may block the light L from being irradiated onto the third package P3 during the seventh section, so the temperature of the third package P3 may decrease.

For example, the third package P3 and the second shutter 232 may move in the first horizontal or X direction at the same speed. The third package P3 and the second shutter 232 may move relatively slowly. For example, a moving speed of the third package P3 and the second shutter 232 may be about ‘10 mm/s’.

For example, a length in the first horizontal or X direction of the second shutter 232 may be greater than or equal to a length in the first horizontal or X direction of the third package P3. Additionally, the second shutter 232 may be moved depending on a position of the second side portion S32 of the third package P3. Accordingly, the irradiation of the third package P3 may be blocked while the third package P3 exits the irradiation region IR, so that it may be possible to prevent portions of connecting members included in the third package P3 from being partially heated or partially cooled.

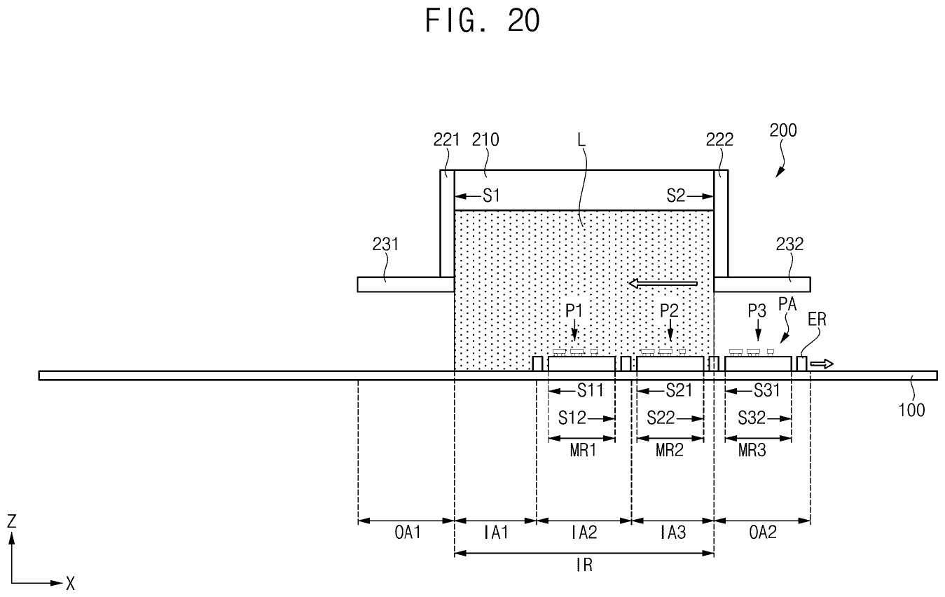

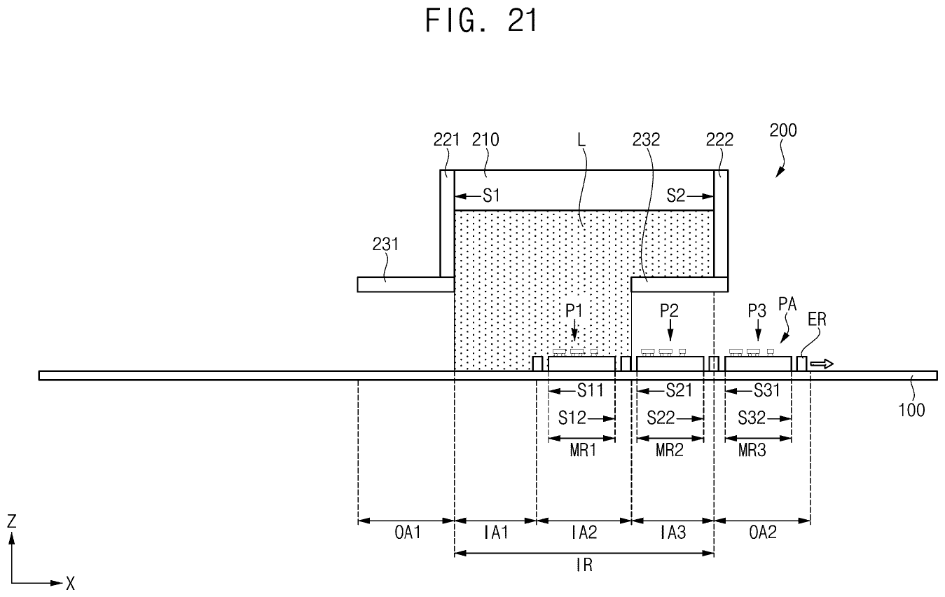

FIGS. 20 and 21 are cross-sectional views illustrating the package array irradiated by light in the eighth time period TP8 of FIG. 6.

Referring to FIGS. 20 and 21, the second shutter 232 may be moved from the second external region OA2 to the third irradiation region IA3 to block light L that would otherwise irradiate the second package P2 provided on the third irradiation region IA3. Additionally, light L may continue to irradiate the first package P1 provided on the second irradiation region IA2.

For example, the time period when the second shutter 232 move from the second external region OA2 to the third irradiation region OA3 after the second package P2 enters the third irradiation region IA3 may be the eighth time period TP8. During the eighth time period TP8, the light L irradiated onto the second package P2 provided on the third irradiation region OA3 may begin to be blocked, so the temperature of the second package P2 may decrease. Additionally, the temperature of the first package P1 may increase since the light L continues to irradiate the first package P1 disposed on the second irradiation region IA2.

For example, the second shutter 232 may move relatively quickly from the second external region OA2 to the third irradiation region IA3. For example, while the light irradiated from the lamp heater 200 is turned off, the second shutter 232 may move from the second external region OA2 to the third irradiation region IA3. For example, the time period during which the light irradiated from the lamp heater is repeatedly turned off may be about ‘248 ms’.

Accordingly, while the second shutter 232 is moved from the second external region OA2 to the third irradiation region IA3, the temperature gradient in the second package P2 may be prevented from increasing. In addition, since the time period for which the second package P2 is irradiated to light is the same as the time period for which the third package P3 is irradiated to light, it may be possible to prevent difference of the temperature gradients between the packages included in the package array PA from increasing.

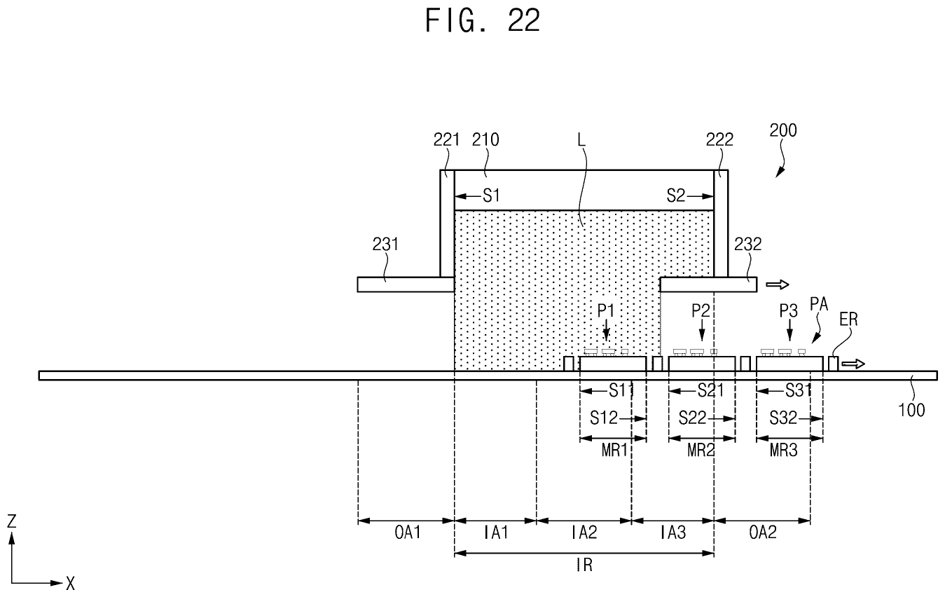

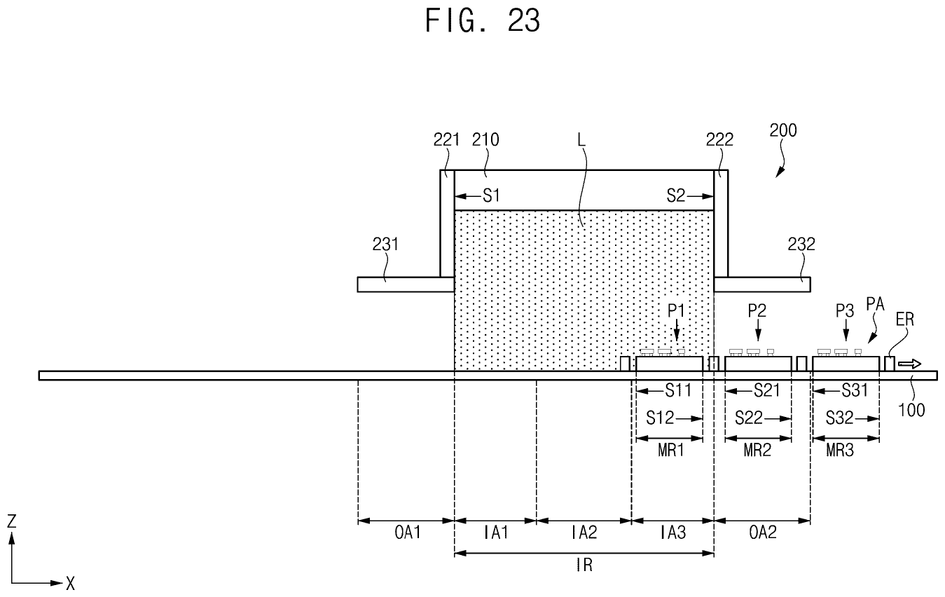

FIGS. 22 and 23 are cross-sectional views illustrating the package array irradiated by light in the ninth time period TP9 of FIG. 6.

Referring to FIGS. 22 and 23, the second package P2 and the second shutter 232 disposed over the second package P2 may be moved together from the third irradiation region OA3 to the second external region OA2. Thus, the second package P2 may exit the irradiation region IR while blocking the light L that would otherwise irradiate the second package P2. In addition, while the second package P2 exits the third irradiation region IA3, the first package P1 may be moved from the second irradiation region IA2 to the third irradiation region IA3, and light L may irradiate the first package P1.

For example, the time period for the first package P1 to move from the second irradiation region IA2 to the third irradiation region IA3 may be the ninth time period TP9. During the ninth time period TP9, light may be irradiated to the first package P1, so the temperature of the first package P1 may increase. In contrast, the second shutter 232 blocks the light L irradiated onto the second package P2 during the ninth time period TP9, so the temperature of the second package P2 may decrease.

For example, the second package P2 and the second shutter 232 may move in the first horizontal or X direction at the same speed. The second package P2 and the second shutter 232 may move relatively slowly. For example, a moving speed of the second package P2 and the second shutter 232 may be about ‘10 mm/s’.

For example, a length in the first horizontal or X direction of the second shutter 232 may be greater than or equal to a length in the first horizontal or X direction of the second package P2. Additionally, the second shutter 232 may be moved depending on a position of the second side portion S22 of the second package P2. Accordingly, the irradiation of the second package P2 may be blocked while the second package P2 exits the irradiation region IR, so it may be possible to prevent portions of connecting members included in the second package P2 from being partially heated or partially cooled.

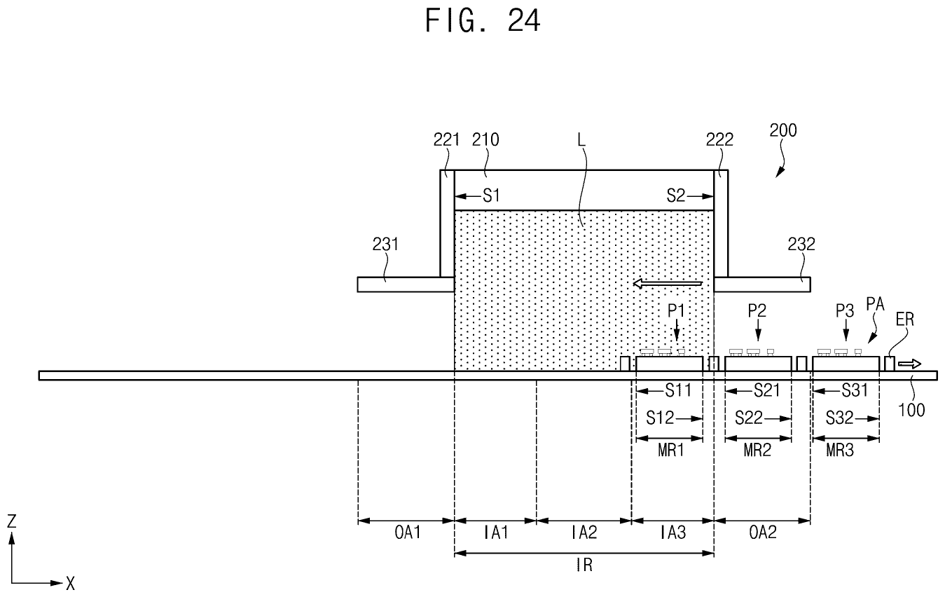

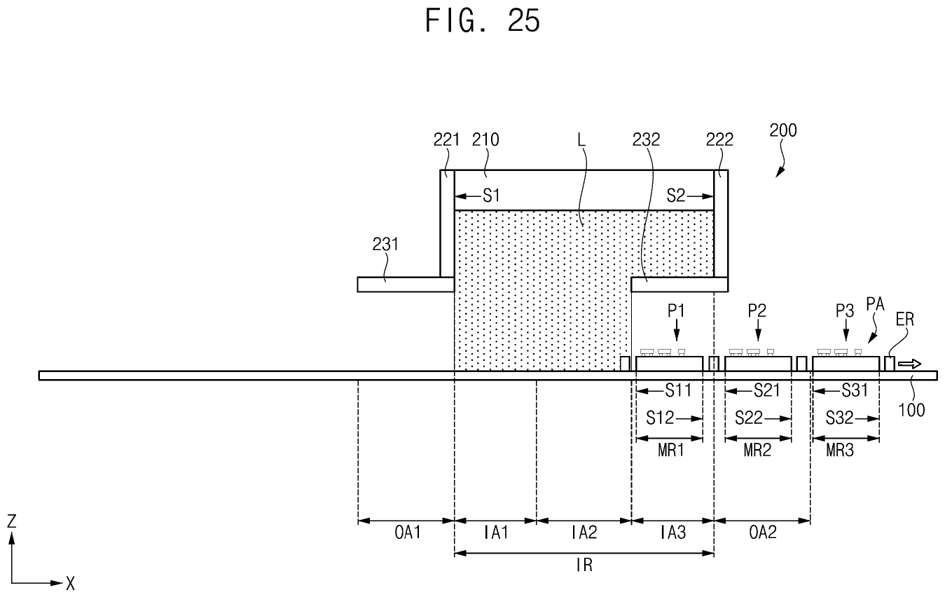

FIGS. 24 and 25 are cross-sectional views illustrating the package array irradiated by light in the tenth time period TP10 of FIG. 6.

FIGS. 24 and 25, the second shutter 232 may be moved from the second external region OA2 to the third irradiation region IA3 to block light L that would otherwise irradiate the first package P1 disposed on the third irradiation region IA3. For example, the time period when the second shutter 232 moves from the second external region OA2 to the third irradiation region OA3 after the first package P1 enters the third irradiation region IA3 may be the tenth time period TP10. During the tenth time period 110, the light L irradiated onto the first package P1 disposed on the third irradiation region OA3 may begin to be blocked, so the temperature of the first package P1 may decrease.

For example, the second shutter 232 may move relatively quickly from the second external region OA2 to the third irradiation region IA3. For example, while the light irradiated from the lamp heating portion is turned off, the second shutter 232 may move from the second external region OA2 to the third irradiation region IA3. For example, the time period during which the light irradiated from the lamp heater is repeatedly turned off may be about ‘248 ms’.

Accordingly, while moving the second shutter 232 from the second external region OA2 to the third irradiation region IA3, the temperature gradient in the first package P1 may be prevented from increasing. In addition, since the time period for which the first package P1 is irradiated to light is the same as the time period for which the second package P2 and the third package P3 are irradiated to light, it may be possible to prevent difference of temperature gradients between the packages included in the package array PA from increasing.

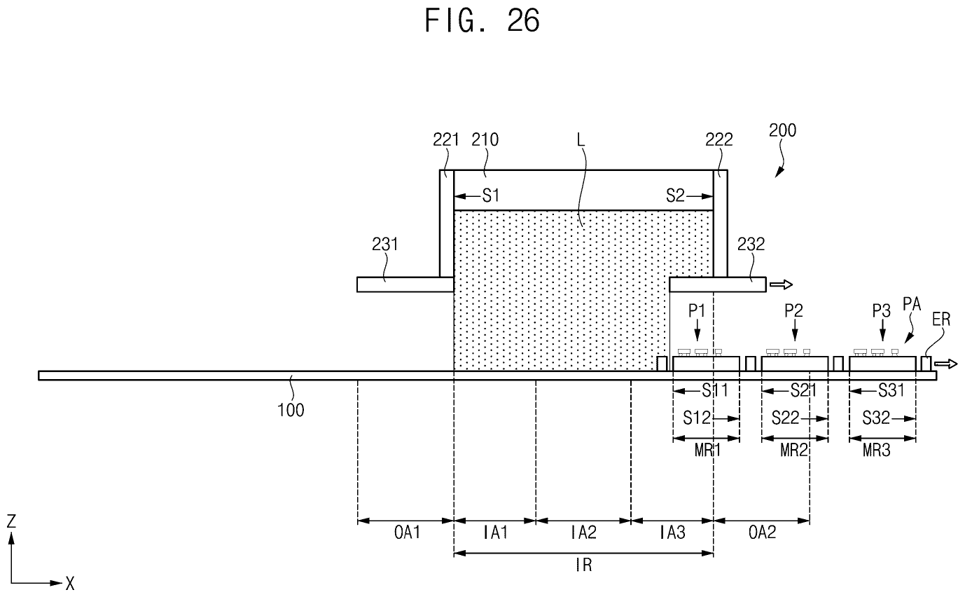

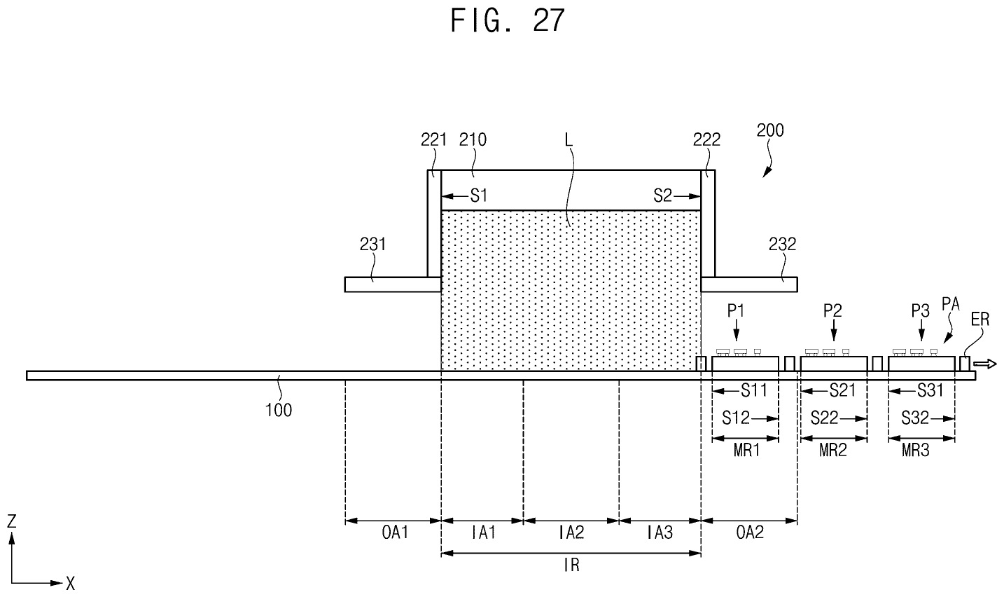

FIGS. 26 and 27 are cross-sectional views illustrating the package array irradiated by light in the eleventh time period TP11 of FIG. 6.

Referring to FIGS. 26 and 27, the first package P1 and the second shutter 232 disposed over the first package P1 may be moved together from the third irradiation region OA3 to the second external region OA2. Accordingly, the first package P1 may exit the irradiation region IR while blocking the light L that would otherwise irradiate the first package P1. Thus, the soldering processes of the package array PA including the plurality of packages may be completed.

For example, the time period for the first package P1 to move from the third irradiation region IA3 to the second external region OA2 may be the eleventh time period TP11. The second shutter 232 may block the light L irradiated onto the first package P1 during the eleventh time period TP11, so the temperature of the first package P1 may decrease.

For example, the first package P1 and the second shutter 232 may move in the first horizontal or X direction at the same speed. The first package P1 and the second shutter 232 may move relatively slowly. For example, a moving speed of the first package P1 and the second shutter 232 may be about ‘10 mm/s’.

For example, a length in the first horizontal or X direction of the second shutter 232 may be greater than or equal to a length in the first horizontal or first direction of the first package P1. Additionally, the second shutter 232 may be moved depending on a position of a second side portion S12 of the first package P1. Accordingly, since the irradiation of the first package P1 is blocked while the first package P1 exits the irradiation region IR, it may be possible to prevent portions of connecting members included in the first package P1 from being locally heated or locally cooled.

As mentioned above, in the method of soldering electronic devices, the first shutter may 231 be moved from the first external region OA1 to the first irradiation region IA1 with the package that enters into the irradiation region IR, to block light L from being irradiated onto the package. The first shutter 231 may be moved from the first irradiation region IA1 to the first external region OA1 to allow light L to irradiate the package on the first irradiation region IA1. Additionally, the second shutter 232 may be moved from the second external region OA2 to the third irradiation region IA3 to block light L from being irradiated onto the package that is provided on the third irradiation region IA3. The second shutter 232 may be moved from the third irradiation region IA3 to the second external region OA2 together with the package that exits the irradiation region IR to block irradiation of the package.

Accordingly, a method of soldering electronic devices may prevent temperature gradients from occurring when a package included in a package array enters an irradiation region or when the package exits the irradiation region. Additionally, a method of soldering electronic devices may prevent a temperature gradient between packages included in the package array from increasing by equalizing times for which the packages are irradiated with light, respectively. Thus, it may be possible to prevent tilting of the electronic devices and/or a tombstone defect where the electronic device stands somewhat vertically by surface tension of molten solder balls for some solder balls on one side portion of the electronic device that have melted faster or cooled slower than other solder balls.

The semiconductor package may include semiconductor devices such as logic devices, memory devices, or the like. The semiconductor package may include logic devices such as central processing units (CPUs), main processing units (MPUs), application processors (APs), or the like, and volatile memory devices such as dynamic random-access memory (DRAM) devices, high bandwidth memory (HBM) devices, or non-volatile memory devices such as flash memory devices, phase-change random-access memory (PRAM) devices, magneto-resistive random-access memory (MRAM) devices, resistive random-access memory (ReRAM) devices, or the like.

The foregoing is illustrative of an embodiment and is not to be construed as limiting thereof. For example, although a movable substrate supply actuator is shown and described, alternate embodiments may employ a stationary substrate platform where the light portion, shutter portion and/or light irradiation pattern moves relative to the substrate platform, without limitation thereto.

Although illustrative embodiments have been described, those of ordinary skill in the pertinent art will readily appreciate that many modifications are possible in alternate embodiments without materially departing from the novel teachings of the present disclosure. Accordingly, all such modifications are intended to be included within the scope of the disclosure as defined in the following claims.

1. A method of soldering electronic devices, the method comprising:
providing a lamp heater including a light-emitting portion and a shutter portion, wherein the light-emitting portion is configured to irradiate with light a first irradiation region, a second irradiation region, and a third irradiation region that are sequentially arranged in a first direction, wherein the shutter portion includes a first shutter configured to block the light to the first irradiation region and a second shutter configured to block the light to the third irradiation region;
disposing a package array on a substrate supply actuator, wherein the package array includes a first package and a second package that are sequentially disposed along the first direction;
moving the substrate supply actuator in the first direction to sequentially pass the package array through the first irradiation region, the second irradiation region and the third irradiation region; and
performing soldering processes on the first package and the second package by selectively blocking the light to the first irradiation region and the light to the third irradiation region while the first package and the second package move through the first irradiation region, the second irradiation region and the third irradiation region.

2. The method of claim 1, wherein blocking the light to the first irradiation region includes, when at least one of the first package and the second package enter the first irradiation region, moving the first shutter together with at least one of the first package and the second package so that the first shutter is disposed over at least one of the first package and the second package to block the light onto at least one of the first package and the second package.

3. The method of claim 2, wherein performing the soldering process on the first package and the second package includes, after at least one of the first package and the second package enters the first irradiation region, moving the first shutter from above at least one of the first package and the second package to allow at least one of the first package and the second package to be irradiated with the light on the first irradiation region.

4. The method of claim 3,
wherein moving the first shutter together with at least one of the first package and the second package so that the first shutter is disposed over at least one of the first package and the second package includes moving the first shutter at a first speed from an external region adjacent to the first irradiation region to the first irradiation region, and
wherein moving the first shutter from above at least one of the first package and the second package includes moving the first shutter at a second speed greater than the first speed from the first irradiation region to the external region.

5. The method of claim 1, wherein blocking the light to the third irradiation region includes, after at least one of the first package and the second package enter the third irradiation region, moving the second shutter to be disposed over at least one of the first package and the second package to block the light onto at least one of the first package and the second package.

6. The method of claim 5, wherein blocking the light to the third irradiation region includes, when at least one of the first package and the second package exits the third irradiation region, moving the second shutter together with at least one of the first package and the second package so that the second shutter is disposed over at least one of the first package and the second package to block the light onto at least one of the first package and the second package.

7. The method of claim 6,
wherein moving the second shutter so that the second shutter is disposed over at least one of the first package and the second package includes moving the second shutter at a first speed from an external region adjacent to the third irradiation region to the third irradiation region, and
wherein moving the second shutter together with at least one of the first package and the second package includes moving the second shutter at a second speed less than the first speed from the third irradiation region to the external region.

8. The method of claim 1, wherein the light-emitting portion irradiates the package array with pulsed light by using a xenon (Xe) lamp.

9. A method of soldering electronic devices, the method comprising:
providing a lamp heater including a light-emitting portion and a shutter portion, wherein the light-emitting portion is configured to irradiate with light a first irradiation region, a second irradiation region and a third irradiation region that are sequentially arranged in a first direction, wherein the shutter portion includes a first shutter configured to selectively block the light to the first irradiation region and a second shutter configured to selectively block the light to the third irradiation region;
sequentially disposing a first package and a second package in the first direction on a substrate supply actuator to sequentially pass the first package and the second package through the first irradiation region, the second irradiation region and the third irradiation region;
moving the substrate supply actuator in the first direction so the second package enters the first irradiation region;
irradiating the second package through the first shutter during a first time period while the second package is in the first irradiation region;
irradiating the second package during a second time period while moving the second package to the second irradiation region, and blocking the first package from being irradiated using the first shutter during the second time period while moving the first package to the first irradiation region;
irradiating the second package during a third time period while the second package is in the second irradiation region, and irradiating the first package through the first shutter during the third time period while the first package is in the first irradiation region;
irradiating the first package during a fourth time period while moving the first package to the second irradiation region, and irradiating the second package during the fourth time period while moving the second package to the third irradiation region;
irradiating the first package during a fifth time period while the first package is in the second irradiation region, and blocking the second package from being irradiated using the second shutter during the fifth time period while the second package is in the third irradiation region;
irradiating the first package during a sixth time period while moving the first package to the third irradiation region, and blocking the second package from being irradiated using the second shutter during the sixth time period while the second package exits the third irradiation region; and
blocking the first package from being irradiated while the first package exits the third irradiation region.

10. The method of claim 9, wherein each of the first time period, the third time period, and the fifth time period is less than each of the second time period, the fourth time period, and the sixth time period.

11. The method of claim 9, wherein blocking the irradiation of the first package or the second package includes moving the first shutter together with the first package or the second package such that the first shutter is disposed over the first package or the second package when the first package or the second package enters the first irradiation region.

12. The method of claim 11, wherein allowing the light to irradiate the first package by the first shutter includes moving the first shutter from above the first package to allow the light to irradiate the first package after the first package enters the first irradiation region.

13. The method of claim 9, wherein blocking the irradiation of the third irradiation region by second shutter includes moving the second shutter such that the second shutter is disposed above at least one of the first package and the second package when at least one of the first package and the second package is disposed on the third irradiation region.

14. The method of claim 13, wherein blocking the irradiation of at least one of the first package and the second package include moving the second shutter together with at least one of the first package and the second package such that the second shutter is disposed over at least one of the first package and the second package when at least one of the first package and the second package exits from the third irradiation region.

15. A method of manufacturing a semiconductor package, the method comprising:
sequentially disposing a plurality of packages on a substrate supply actuator in a first direction;
moving the substrate supply actuator in the first direction to sequentially pass the plurality of packages through a first irradiation region, a second irradiation region and a third irradiation region that are sequentially arranged in the first direction; and
performing a soldering process on each of the plurality of packages by irradiating the first irradiation region, the second irradiation region and the third irradiation region, and selectively blocking irradiation of the first irradiation region and the third irradiation region while the plurality of packages sequentially move through the first irradiation region, the second irradiation region and the third irradiation region,
wherein performing the soldering process includes:
irradiating a first package during a first time period while moving the first package into the second irradiation region, and blocking irradiation of a second package while the second package enters the first irradiation region;
irradiating the first package and the second package during a second time period while moving the first package to the third irradiation region and moving the second package to the second irradiation region, and blocking irradiation of a third package while the third package enters the first irradiation region; and
irradiating the second package and the third package during a third time period while moving the second package to the third irradiation region and moving the third package to the second irradiation region, and blocking irradiation of the first package while the first package exits the third irradiation region.

16. The method of claim 15, wherein performing the soldering process on each of the plurality of packages includes blocking the irradiation of a portion of each of the plurality of packages when each of the plurality of packages enters the first irradiation region.

17. The method of claim 16, wherein blocking the irradiation of the portion of each of the plurality of packages when each of the plurality of packages enters the first irradiation region includes moving a shutter together with each of the plurality of packages such that the shutter is disposed over each of the plurality of packages when each of the plurality of packages enters the first irradiation region.

18. The method of claim 16, wherein performing the soldering process on each of the plurality of packages includes moving a shutter from above each of the plurality of packages to allow the light to irradiate each of the plurality of packages after each of the plurality of packages enters the first irradiation region.

19. The method of claim 15, wherein performing the soldering process on each of the plurality of packages includes blocking the irradiation of a portion of each of the plurality of packages when each of the plurality of packages exits the third irradiation region.

20. The method of claim 19, wherein blocking the irradiation of a portion of each of the plurality of packages when each of the plurality of packages exits the third irradiation region includes moving a shutter together with each of the plurality of packages such that the shutter is disposed over each of the plurality of packages when each of the plurality of packages exits the third irradiation region.

21-28. (canceled)
